(19) United States
(12) Patent Application Publication
(10) Pub. No.: US 2024/0304581 A1
(43) Pub. Date: Sep. 12, 2024

(54) Coating of Nanowires

(71) Applicant: NanoWired GmbH

(72) Inventors: Olav Birlem, Gernsheim (DE); Florian Dassinger, Gernsheim (DE); Sebastian Quednau, Gernsheim (DE); Farough Roustaie, Gernsheim (DE)

(73) Assignee: NanoWired GmbH, Gernsheim (DE)

(21) Appl. No.: 18/279,487

(22) PCT Filed: Feb. 22, 2022
(86) PCT No.: PCT/EP2022/054379

§ 371 Date: Aug. 30, 2023

(30) Foreign Application Priority Data
Mar. 3, 2021 (DE) 10 2021 105 129.0

(51) Int. Cl. H01L 23/00; H05K 3/28; H05K 3/36

(52) U.S. Cl. CPC H01L 24/11; H01L 24/13; H01L 24/16; H01L 24/81; H05K 3/282; H05K 3/368; H01L 2224/11823; H01L 2224/13111; H01L 2224/13139; H01L 2224/13144; H01L 2224/13147; H01L 2224/13155; H01L 2224/13169; H01L 2224/1357; H01L 2224/13639; H01L 2224/13644; H01L 2224/13693; H01L 2224/16145; H01L 2224/16225; H01L 2224/81897

(57) ABSTRACT

Method for applying a coating to a plurality of nanowires on a component, the method comprising:
a) treating the nanowires with a reducing substance,
b) immersing the nanowires in a protective substance,
c) drying the nanowires, so that the coating is obtained from the protective substance.

The invention relates to a method for applying a coating to a plurality of nanowires on a component and to a method for connecting two components by way of a plurality of nanowires, which according to the invention may in particular be coated.

It is known to provide nanowires with a protective lacquer after they have been grown. The protective lacquer temporarily protects the nanowires until they have been passed on for their intended use. For example, the nanowires may be used for connecting two components to one another. The protective lacquer encloses the nanowires in their entirety. Before the nanowires can be passed on for their intended use, the nanowires must be stripped. For this, the protective lacquer has to be chemically removed. This represents an additional method step and to this extent is unfavourable. Also, it requires a chemical, which may in particular be liquid or gaseous. Liquid chemicals are generally undesired in production environments. Moreover, liquids can leave residues behind on the treated component. The use of gaseous chemicals requires the creation of a corresponding atmosphere, which is laborious.

The object of the present invention is to provide a possibility on the basis of the described prior art by which nanowires can be protected in such a way that the protection can be removed easily and without leaving residues.

These objects are achieved by the methods according to the independent claims. Further advantageous configurations are indicated in the dependent claims. The features represented in the claims and in the description can be combined with one another in any technologically meaningful way.

According to the invention, a method for applying a coating to a plurality of nanowires on a component is provided. The method comprises:
a) treating the nanowires with a reducing substance,
b) immersing the nanowires in a protective substance,
c) drying the nanowires, so that the coating is obtained from the protective substance.

Steps a), b) and c) are preferably carried out in the sequence given.

With the described method, the nanowires can be protected by the coating until they have been passed on for their intended use. That may be connecting the component in which the nanowires are located to a further component. However, the method is also suitable for other application purposes. The coating obtained by the method can in particular be easily removed, in particular without the use of chemicals. In some applications, it is even possible to dispense with removing the coating.

With the described method, nanowires can be protected. A nanowire is understood here as meaning any body of material that has a wire-like form and a size in the range of a few nanometres to a few micrometres. A nanowire may for example have a circular, oval or polygonal base area. In particular, a nanowire may have a hexagonal base area.

The nanowires preferably have a length in the range from 100 nm [nanometres] to 100 μm [micrometres], in particular in the range from 500 nm to 60 μm. The nanowires also preferably have a diameter in the range from 10 nm to 10 μm, in particular in the range from 30 nm to 2 μm. Here, the term diameter relates to a circular base area, a comparable definition of a diameter being applicable if the base area deviates from this. It is particularly preferred that all of the nanowires used have the same length and the same diameter.

The described method can be used for a wide variety of materials of the nanowires. Electrically conducting materials, in particular metals such as copper, silver, gold, nickel, tin and platinum, are preferred as the material of the nanowires. However, non-conducting materials, such as metal oxides, are also preferred. Preferably, all of the nanowires are formed from the same material.

The nanowires may have been obtained by being galvanically grown on the component. The nanowires have preferably been grown onto an electrically conducting surface of the component. If the surface is part of a component that is otherwise not electrically conducting, the electrical conductivity can be achieved for example by a metallization. Thus, for example, a substrate that is not electrically conducting may have been coated with a thin layer of metal in order to grow the nanowires onto the thin layer of metal.

The nanowires preferably stand perpendicularly on the surface of the component. Preferably, a respective first end of the nanowires is connected to the surface of the component. A respective second end of the nanowires is preferably arranged at a distance from the surface. However, it is also conceivable for example that the method is applied to nanowires that lie on the surface of the component.

The component may be in particular an electronic component. For example, the component may be a substrate, a silicon chip or a so-called printed circuit board (PCB). The method may however also be applied to any other type of component.

In step a), the nanowires are treated with a reducing substance. Any chemical substance that has a reducing effect on the surface of the nanowires comes into consideration as the reducing substance. Step a) may alternatively also be devised in such a way that a surface of the nanowires is reduced. This should be understood as meaning a chemical reduction. In step a), in particular oxides on the surface of the nanowires are removed.

The reducing substance may be liquid or gaseous. For example, the reducing substance may take the form of vapour. The reducing substance is preferably an acid. For example, the reducing substance may be formic acid, in particular formic acid vapour. Alternatively, the reducing substance may be liquid citric acid, forming gas (forming acid) or hydrogen plasma.

The treatment of the nanowires in step a) preferably takes place by the nanowires being subjected to the reducing substance. In the case of a liquid or gaseous reducing substance, this may take place for example by the nanowires being sprayed with the liquid or gaseous reducing substance. In the case of a gaseous reducing substance, the nanowires may be exposed to an atmosphere that contains the reducing substance.

In step b), the nanowires are immersed in a protective substance. The protective substance is preferably liquid. Any chemical substance that is deposited on the surface of the nanowires when the nanowires are immersed in the protective substance and from which a coating forms on the nanowires by drying comes into consideration as the protective substance. This takes place in step c), in which the nanowires are dried. This may take place actively or passively. It is active drying if a measure is taken to act on the nanowires. For example, the nanowires may be exposed to a gas stream and/or be heated. It is passive drying if the nanowires dry because they are exposed to their environment, without any particular measure being taken for drying the nanowires.

With the described method, a coating of the nanowires is obtained. A coating of the nanowires should be understood as meaning a layer on the surface of the nanowires. The coating therefore follows the form of the nanowires. The nanowires coated with the coating represent a structure which is likewise covered by the above definition of the term nanowire. The coating is formed in such a way that a clearance is formed between the coating on nanowires adjacent to one another. The nanowires are therefore at a distance from one another in spite of the coating. A protective lacquer which encloses the nanowires in their entirety is consequently not a coating of the nanowires in the sense used here. Instead, such a protective lacquer would form a coating of the surface of the component in which the nanowires are enclosed.

The coating can be removed particularly easily when the nanowires have been passed on for their intended use. No chemicals are required for this. To this extent, the disadvantages known from the prior art are overcome. That chemicals are required for forming the protection is in this case immaterial. Thus, it is usually possible without difficulty to use chemicals for forming a protection. Finally, the protection is applied where the nanowires have also been grown. This in any case requires the use of chemicals. The problems described with reference to the prior art relate to the removal of the protection by chemicals being disadvantageous. The reason for this is that the protection has to be removed at the location where the nanowires have been passed on for their intended use. As a result of the described method, that may be a location at which no chemicals can be used or are intended to be used.

In a preferred embodiment of the method, the protective substance comprises an organic substance.

It has been found that even a layer of a few molecules of an organic substance is sufficient to protect the surface of the nanowires from oxidation.

Preferred as the protective substance in this embodiment are: benzotriazole, imidazole, polyvinylpyrrolidone, benzimidazole, thiol-based substances or mercaptobenzimidazole.

In a further preferred embodiment of the method, the protective substance comprises a metal.

It has been found that even a layer of a few atoms of a metal is sufficient to protect the surface of the nanowires from oxidation. The metal is preferably a precious metal. For step b), the metal is preferably provided in the form of an immersion bath. This can take place by means of a corresponding temperature and/or by the metal being dissolved in a solvent. Thus, the protective substance preferably comprises a solvent. The solvent may evaporate in step c). The coating is in that case formed by part of the protective substance that does not evaporate as solvent.

Preferred as the protective substance in this embodiment are: silver and gold.

In a further preferred embodiment of the method, the protective substance is chosen in consideration of the material of the nanowires such that in step b) the protective substance is at least partially deposited on the nanowires by physisorption.

In the physisorption, molecules and/or atoms from the protective substance are deposited on the surface of the nanowires by Van-der-Waals forces. The case where in step b) the protective substance is only partially deposited on the nanowires by physisorption may arise for example because the protective substance contains a solvent and only the other components of the protective substance are deposited on the surface of the nanowires.

In a further preferred embodiment of the method, the coating on the nanowires formed by steps a) to c) has an average thickness of at most 20 atomic layers or molecular layers, in particular of at most 10 atomic layers or molecular layers.

This small thickness of the coating allows the coating to remain on the nanowires when they are passed on for their intended use. Thus, the component with the nanowires may for example be connected by way of the plurality of nanowires to a further component without the coating having to be removed. The connection may be formed by way of the coating between the nanowires and a surface of the further component or by way of the coating between the nanowires and nanowires on the surface of the further component. The nanowires on the surface of the further component are preferably likewise coated, so that the connection between the coatings is formed. Alternatively, the coating can be easily removed mechanically, for example by the nanowires coming into contact with the surface of the further component or with nanowires on it. By heating, the coating can also be broken down.

A coating with the described small thickness can be obtained by steps a) to c). The thickness is influenced in particular by the material of the nanowires, the chemical composition of the reducing substance used in step a), the chemical composition of the protective substance used in step b), in particular the concentration of the reducing substance, and also by process parameters such as the duration of steps a), b) and c) or the temperature of the nanowires during steps a), b) and c). How these factors are to be chosen for a desired thickness of the coating can be determined by experiments.

If the coating is formed from atoms, the coating has an average thickness of at most 20 atomic layers, in particular at most 10 atomic layers. If the coating is formed from molecules, the coating has an average thickness of at most 20 molecular layers, in particular at most 10 molecular layers.

In a further preferred embodiment of the method, the component is rinsed with a rinsing fluid between steps a) and b) and/or between steps b) and c). The “and” case is preferred.

The rinsing allows a particularly thin coating to be obtained. A solvent such as water comes into consideration in particular as the rinsing fluid. The rinsing between step a) and step b) allows an interaction between the reducing substance and the protective substance to be prevented. The rinsing between step b) and step c) allows constituents of the protective substance to be removed, so that they are not deposited as undesired residues on the nanowires in step c).

As a further aspect of the invention, a method for connecting two components by way of a plurality of nanowires is provided. The method comprises:
A) providing a plurality of nanowires with a coating on at least one of the components,
B) bringing the components together, so that the components are connected to one another by way of the nanowires.

The described advantages and features of the method for applying a coating to a plurality of nanowires on a component can be applied and transferred to the method for connecting two components by way of a plurality of nanowires, and vice versa.

Steps A) and B) are carried out in the sequence given. Preferably, step B) directly follows step A). In particular, it is preferred that the coating is not removed between steps A) and B). If at all, the coating is removed in step B) by the bringing together of the components or in a step following step B). It is therefore preferred that the coating is still present at the beginning of step B).

The nanowires allow the connection to form over a particularly large contact area. As a result, a particularly mechanically stable, electrically conductive and/or thermally conductive connection can be obtained. With the described method, for example two electronic components can be connected to one another. However, the described method is not restricted to applications from the area of electronics.

It is sufficient that the nanowires are provided on one of the two components. In that case, in step B) the nanowires on a first of the components come into contact with the surface of a second of the components by way of the coating. It is conceivable that the coating remains between the nanowires and the surface of the second component. Alternatively, the coating may be removed in places or in full by the bringing together of the two components or by a subsequent method step. Wherever the coating is removed, there is direct contact between the nanowires and the surface of the second component. Whether and to what extent the coating is removed when the two components are brought together may depend on the thickness of the coating, on the material of the coating, on the material of the surface of the second component and/or on the material of the nanowires.

Alternatively, in step A) a plurality of nanowires may be provided on each of the two components. Preferably, the nanowires of both components are coated with a respective coating. In step B), the nanowires on a first of the components come into contact with the nanowires on the second component by way of the respective coating. If the nanowires on both components are coated, the contact is created between coating and coating. The coatings may remain between the nanowires. Alternatively, the coatings may be removed in places or in full by the bringing together of the two components or in a subsequent method step. Wherever the coating is removed, there is direct contact between the nanowires. Whether and to what extent the coating is removed when the two components are brought together may depend on the thickness of the coating, on the material of the coating, on the material of the surface of the second component and/or on the material of the nanowires.

In a preferred embodiment, the coating is obtained in step A) by the described method for applying the coating to a plurality of nanowires on a component.

If in step A) the nanowires are only provided on one of the components, the previously described method for applying a coating to a plurality of nanowires on a component is applied to the nanowires on this component. If in step A) the nanowires are provided on both components, the previously described method for applying a coating to a plurality of nanowires on a component is respectively applied to the nanowires on both components.

The connection of the two components may already be formed at room temperature. This applies in particular to the case where the nanowires are provided on both components.

In a further preferred embodiment, the method also comprises:
C) at least partially removing the coating of the nanowires by heating.

Step C) is preferably carried out after step B). The heating allows the coating to be partially removed, preferably completely removed. The heating preferably takes place to a temperature of at least 90° C., in particular to a temperature in the range from 90 to 150° C.

The heating is preferred in particular in the case where the nanowires in step A) are only provided on one of the two components. In that case, the heating preferably takes place to a temperature of at least 170° C., in particular to a temperature in the range from 170 to 230° C. The heating allows the nanowires on the first component to be connected particularly well to the surface of the second component.

The heating allows the nanowires to be connected to one another in such a way that subsequently the nanowires can no longer be seen as such.

The invention is explained in more detail below on the basis of the figures. The figures show particularly preferred exemplary embodiments, to which however the invention is not restricted. The figures and the relative sizes shown therein are only schematic. In the figures:

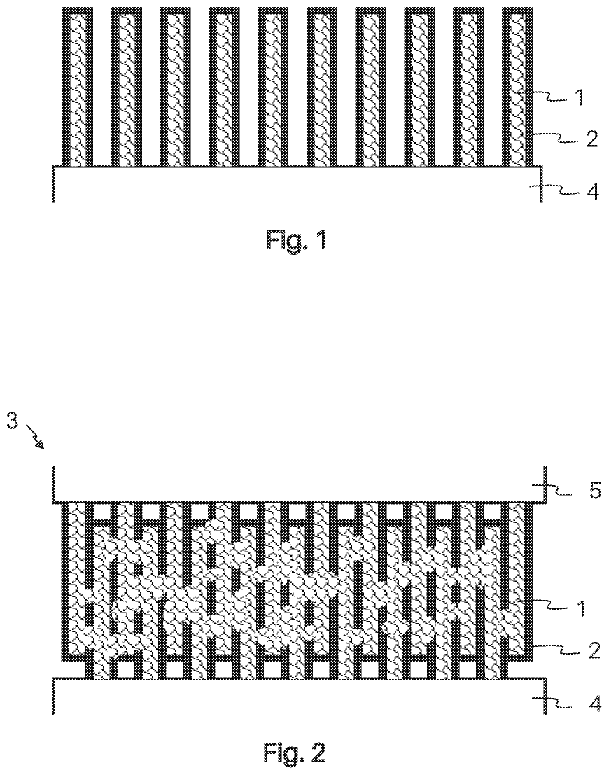

FIG. 1 shows the result of a method according to the invention for applying a coating to a plurality of nanowires on a component,

FIG. 2 shows the result of a first embodiment of a method according to the invention for connecting two components by way of a plurality of nanowires,

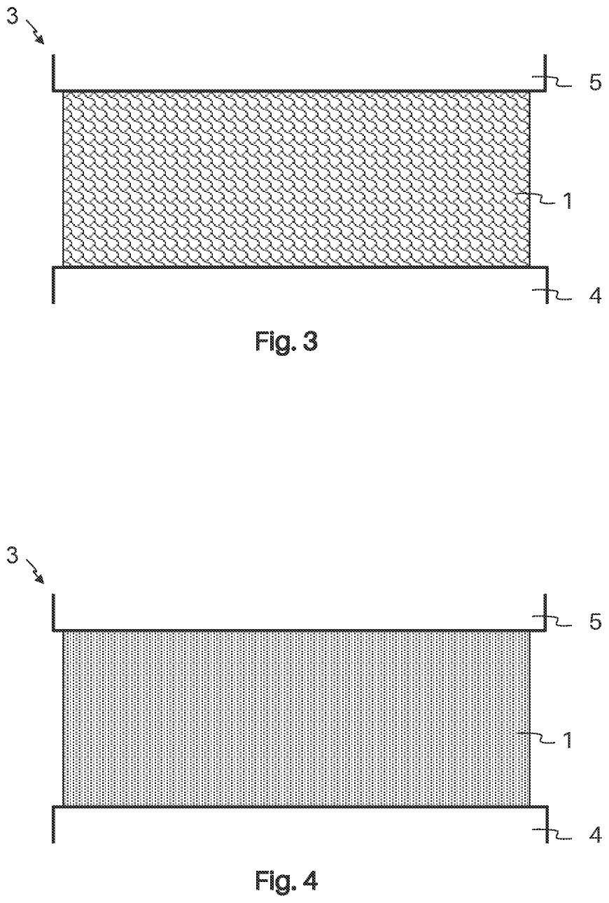

FIG. 3 shows the result of a second embodiment of a method according to the invention for connecting two components by way of a plurality of nanowires,

FIG. 4 shows the result of a third embodiment of a method according to the invention for connecting two components by way of a plurality of nanowires.

FIG. 1 shows a component 4 with a plurality of nanowires 1, which have a coating 2.

The coating 2 was obtained by the following method:
a) treating the nanowires 1 with a reducing substance,
b) immersing the nanowires 1 in a protective substance,
c) drying the nanowires 1, so that the coating 2 is obtained from the protective substance.

The protective substance may comprise an organic substance and/or a metal. The protective substance was chosen in consideration of the material of the nanowires 1 such that in step b) the protective substance is at least partially deposited on the nanowires 1 by physisorption. The coating 2 formed by steps a) to c) has on the nanowires 1 an average thickness of at most 20 atomic layers or molecular layers. The component 4 is rinsed with a rinsing fluid between steps a) and b) and between steps b) and c).

FIG. 2 shows an arrangement 3 with a first component 4 and a second component 5. The two components 4, 5 are connected to one another by way of a plurality of nanowires 1. The nanowires 1 have a coating 2. The arrangement 3 was obtained by a method which comprises:
A) providing a plurality of nanowires 1 with a coating 2 on the two components 4, 5,
B) bringing the two components 4, 5 together, so that the two components 4, 5 are connected to one another by way of the nanowires 1.

In the embodiment shown, the coating 2 has been partially retained in step B) by nanowires 1 that are adjacent to one another being connected to one another by way of the coating 2. It is also evident however that the coating 2 between the nanowires 1 is broken open in places. That has been caused by the bringing together of the components 4, 5. At the places where it is broken open, the nanowires 1 are held against one another particularly well. It should be noted that the figures are only schematic. In particular, the coating 2 is shown disproportionally thick for purposes of illustration.

FIG. 3 shows a further arrangement 3 with a first component 4 and a second component 5. The two components 4, 5 are connected to one another by way of a plurality of nanowires 1. As a difference from FIG. 2, here the nanowires 1 do not have any coating 2, but are directly connected to one another. This can be obtained by the method described with reference to FIG. 2 also comprising the following step:
C) removing the coating 2 of the nanowires 1 by heating.

By step C), the arrangement 3 shown in FIG. 3 can be obtained from the arrangement 3 shown in FIG. 2. The heating has the effect that the material of the nanowires diffuses in such a way that they are also connected to one another. This gives rise to the situation shown in FIG. 3, in which the nanowires 1 are shown simplified as a single layer of material. Nevertheless, the two components 4, 5 are to be considered as connected to one another by way of the plurality of nanowires 1.

A further arrangement 3 is shown in FIG. 4. This was obtained by a method which comprises:
A) providing a plurality of nanowires 1 with a coating 2 on the first component 4, but not on the second component 5
B) bringing the two components 4, 5 together, so that the two components 4, 5 are connected to one another by way of the plurality of nanowires 1
C) removing the coating 2 of the nanowires 1 by heating.

The heating has the effect that the nanowires 1 are connected to one another as in the case of FIG. 3. In addition, the nanowires are however also connected to the surface of the second component 5. FIG. 4 can be obtained by a higher temperature being used in step C) than for FIG. 3. As a result, the nanowires 1 in FIG. 4 are closer together than in FIG. 3, which is illustrated by the denser structuring of the surface area indicating the nanowires 1.

### LIST OF REFERENCE SIGNS

1 Nanowire
2 Coating
3 Arrangement
4 First component
5 Second component

1. Method for applying a coating to a plurality of nanowires on a component, the method comprising:
a) treating the nanowires with a reducing substance,
b) immersing the nanowires in a protective substance,
c) drying the nanowires, so that the coating is obtained from the protective substance.

2. Method according to claim 1, wherein the protective substance comprises an organic substance.

3. Method according to claim 1, wherein the protective substance comprises a metal.

4. Method according to claim 1, wherein the protective substance is chosen in consideration of the material of the nanowires such that in step b) the protective substance is at least partially deposited on the nanowires by physisorption.

5. Method according to claim 1, wherein the coating on the nanowires formed by steps a) to c) has an average thickness of at most 20 molecular layers.

6. Method according to claim 1, wherein the component is rinsed with a rinsing fluid between steps a) and b) and/or between steps b) and c).

7. Method for connecting two components by way of a plurality of nanowires, comprising:
A) providing a plurality of nanowires with a coating on at least one of the components,
B) bringing the components together, so that the components are connected to one another by way of the nanowires.

8. Method for connecting two components by way of a plurality of nanowires, comprising:
A) providing a plurality of nanowires with a coating on at least one of the components,
B) bringing the components together, so that the components are connected to one another by way of the nanowires,
wherein the coating is obtained in step A) by a method according to claim 1.

9. Method according to claim 7, also comprising:
C) at least partially removing the coating of the nanowires by heating.

10. Method according to claim 2, wherein the protective substance comprises a metal.

11. Method according to claim 2, wherein the protective substance is chosen in consideration of the material of the nanowires such that in step b) the protective substance is at least partially deposited on the nanowires by physisorption.

12. Method according to claim 2, wherein the coating on the nanowires formed by steps a) to c) has an average thickness of at most 20 molecular layers.

13. Method according to claim 2, wherein the component is rinsed with a rinsing fluid between steps a) and b) and/or between steps b) and c).

14. Method according to claim 3, wherein the protective substance comprises a metal.

15. Method according to claim 3, wherein the protective substance is chosen in consideration of the material of the nanowires such that in step b) the protective substance is at least partially deposited on the nanowires by physisorption.

16. Method according to claim 3, wherein the coating on the nanowires formed by steps a) to c) has an average thickness of at most 20 molecular layers.

17. Method according to claim 3, wherein the component is rinsed with a rinsing fluid between steps a) and b) and/or between steps b) and c).

18. Method according to claim 4, wherein the protective substance comprises a metal.

19. Method according to claim 4, wherein the protective substance is chosen in consideration of the material of the nanowires such that in step b) the protective substance is at least partially deposited on the nanowires by physisorption.

20. Method according to claim 4, wherein the coating on the nanowires formed by steps a) to c) has an average thickness of at most 20 molecular layers.
